(19) United States
(12) Patent Application Publication
(10) Pub. No.: US 2022/0310626 A1
(43) Pub. Date: Sep. 29, 2022

(54) METHOD FOR FABRICATING SEMICONDUCTOR DEVICE

(71) Applicant: CHANGXIN MEMORY TECHNOLOGIES, INC., Hefei (CN)

(72) Inventors: Zhongming LIU, Hefei (CN); Longyang CHEN, Hefei (CN); Hongfa WU, Hefei (CN)

(21) Appl. No.: 17/504,536

(22) Filed: Oct. 19, 2021

Related U.S. Application Data
(63) Continuation of application No. PCT/CN2021/113349, filed on Aug. 18, 2021.

(30) Foreign Application Priority Data
Mar. 29, 2021 (CN) 202110334039.7

(51) Int. Cl. H01L 27/108

(52) U.S. Cl. CPC H01L 27/10885

(57) ABSTRACT

There is provided a method for fabricating a semiconductor device. The method includes: forming a plurality of bit line structures spaced on a substrate of the semiconductor device, the plurality of bit line structures extending along a first direction; forming a sacrificial layer between the plurality of bit line structures; placing the semiconductor device in a reaction chamber of an etching apparatus; releasing a carbon source gas into the reaction chamber, and providing an alternative electric field to dissociate the carbon source gas into a plasma carbon source; controlling the plasma carbon source to be deposited on top surfaces of the plurality of bit line structures to form a carbon overcoat; etching the sacrificial layer and a part of the substrate to form a storage node contact hole; and removing the carbon overcoat.

### CROSS-REFERENCE TO RELATED APPLICATION

The present disclosure is a continuation of PCT/CN2021/113349, filed on Aug. 18, 2021, which claims priority to Chinese Patent Application No. 202110334039.7, titled “METHOD FOR FABRICATING SEMICONDUCTOR DEVICE” and filed on Mar. 29, 2021, the entire contents of which are incorporated herein by reference.

### TECHNICAL FIELD

The present disclosure relates to the field of semiconductor fabrication technologies, and more particularly, to a method for fabricating a semiconductor device.

### BACKGROUND

In semiconductor device fabricating processes, after bit line structures are formed by means of deposition and etching processes, storage node contact holes are further formed on a semiconductor substrate corresponding to bit line contact holes between the bit line structures, to facilitate forming storage node contact plugs in the storage node contact holes to further form a capacitor structure.

In the related technologies, the storage node contact holes are generally etched on the semiconductor substrate by means of an etching process, but top of the bit line structures may also etched away. That is, after the storage node contact holes are formed, the top of the bit line structures is worn off, which leads to deviation of size, and thus decreases yield of the entire semiconductor device.

### SUMMARY

Embodiment of the present disclosure provide a method for fabricating a semiconductor device, and the method includes: forming a plurality of bit line structures spaced on a substrate of the semiconductor device, the plurality of bit line structures extending along a first direction; forming a sacrificial layer between the plurality of bit line structures; placing the semiconductor device in a reaction chamber of an etching apparatus; releasing a carbon source gas into the reaction chamber, and providing an alternative electric field to dissociate the carbon source gas into a plasma carbon source; controlling the plasma carbon source to be deposited on top surfaces of the plurality of bit line structures to form a carbon overcoat; etching the sacrificial layer and a part of the substrate to form a storage node contact hole; and removing the carbon overcoat.

### BRIEF DESCRIPTION OF THE DRAWINGS

The above and other features and advantages of the present disclosure will become more apparent from the detailed description of exemplary embodiments with reference to the drawings, in which:

FIG. 1 is a flowchart of a method for fabricating a semiconductor device according to an exemplary embodiment of the present disclosure;

FIG. 2 and FIG. 3 are schematic diagrams of forming a bit line structure of a semiconductor device according to an exemplary embodiment of the present disclosure;

FIG. 4 is a top view of a sacrificial layer formed in a semiconductor device according to an exemplary embodiment of the present disclosure;

FIG. 5 is a schematic cross-sectional view along A-A in FIG. 4;

FIG. 6 is a top view of a spacer layer formed in a semiconductor device according to an exemplary embodiment of the present disclosure;

FIG. 7 is a schematic cross-sectional view along B-B in FIG. 6;

FIG. 8 is a schematic diagram of a semiconductor device obtained after a carbon source gas is dissociated into a plasma carbon source according to an exemplary embodiment of the present disclosure;

FIG. 9 is a schematic diagram of a semiconductor device obtained after a plasma carbon source is deposited onto a bit line structure according to an exemplary embodiment of the present disclosure;

FIG. 10 is a schematic diagram of a semiconductor device with a carbon overcoat formed according to an exemplary embodiment of the present disclosure;

FIG. 11 is a schematic diagram of etching the sacrificial layer and removing the carbon overcoat according to an exemplary embodiment of the present disclosure;

FIG. 12 is a top view of the semiconductor device obtained after a storage node contact hole is formed and the carbon layer is removed according to an exemplary embodiment of the present disclosure;

FIG. 13 is a schematic cross-sectional view along C-C in FIG. 12;

FIG. 14 is a top view of a semiconductor device with a storage node contact plug formed according to an exemplary embodiment of the present disclosure; and

FIG. 15 is a schematic cross-sectional view along D-D in FIG. 14.

Reference numbers in the accompanying drawings:

1-substrate; 2-shallow trench isolation; 3-insulating layer; 4-bit line structure; 41-bit line mandrel structure; 411-bit line contact plug; 412-bit line; 413-insulating cover layer; 42-spacer layer; 421-first spacer layer; 422-second spacer layer; 5-sacrificial layer; 51-initial sacrificial layer; 6-spacer layer; 7-carbon overcoat; 8-storage node contact plug; H1-storage node contact hole; H2-bit line node plug hole; G-carbon source gas; C-plasma carbon source; F1-first direction; and F2-second direction.

### DETAILED DESCRIPTION

Exemplary embodiments will now be described more comprehensively with reference to the accompanying drawings. However, the exemplary embodiments may be carried out in various manners, and shall not be interpreted as being limited to the embodiments set forth herein; instead, providing these embodiments will make the present disclosure more comprehensive and complete, and will fully convey the conception of the exemplary embodiments to those skilled in the art. Throughout the drawings, similar reference signs indicate the same or similar structures, and their detailed description will be omitted.

In the following description of different exemplary embodiments of the present disclosure, it is made with reference to the accompanying drawings, which form a part of the present disclosure, and therein different exemplary structures that can implement various aspects of the present disclosure are shown by way of example. It should be understood that other solutions of components, structures, exemplary apparatuses, systems, and steps may be used, and structural and functional modifications may be made without departing from the scope of the present disclosure. Moreover, although the terms “above”, “between”, “within”, etc. may be used in this specification to describe different exemplary features and elements of the present disclosure, these terms are used herein for convenience only, such as directions of the examples in the drawings. Nothing in this specification should be understood as requiring a three-dimensional direction of the structure to fall within the scope of the present disclosure. In addition, the terms “first”, “second”, etc. in the claims are used only as marks, and are not numerical limitations on their objects.

The flowcharts as shown in the accompanying drawings are merely exemplary description instead of necessarily including all the contents and operations/steps, or necessarily having to be performed in the order set forth. For example, some operations/steps may be broken down, while some operations/steps may be combined or partly combined. Therefore, the actual execution sequences may be changed according to the actual conditions.

In addition, in the description of the present disclosure, “a plurality of” refers to at least two, for example, two, three, etc., unless otherwise expressly specified.

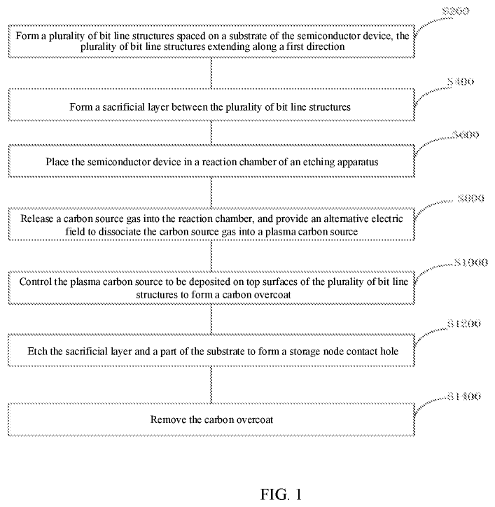

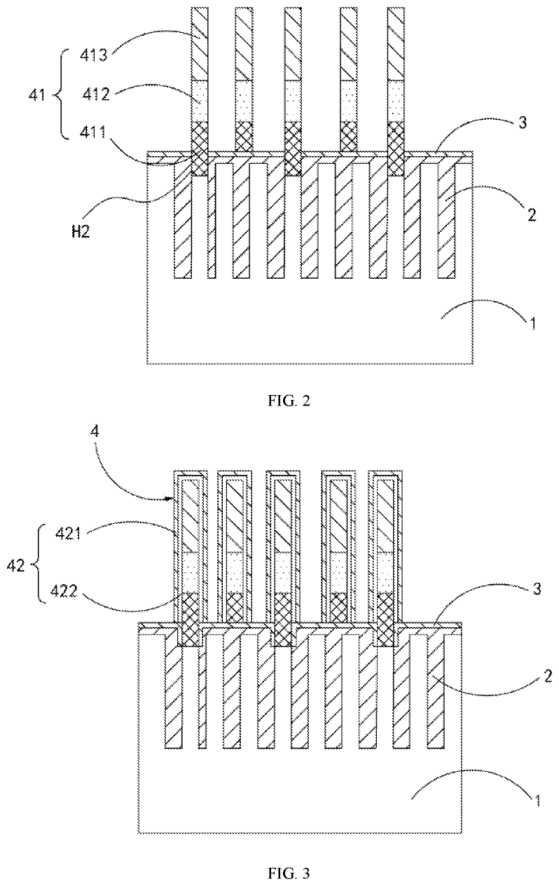

Referring to FIGS. 1 to 15, where FIG. 1 illustrates a flowchart of a method for fabricating a semiconductor device according to an embodiment of the present disclosure, and FIGS. 2 to 15 illustrate different fabrication stages of the semiconductor device according to embodiments of the present disclosure. As shown in FIG. 1 to FIG. 15, the method for fabricating a semiconductor device according to embodiments of the present disclosure includes following steps.

Step S200: forming a plurality of bit line structures 4 spaced on a substrate 1 of the semiconductor device, the plurality of bit line structures extending along a first direction F1.

Step S400: forming a sacrificial layer 5 between the plurality of bit line structures.

Step S600: placing the semiconductor device in a reaction chamber of an etching apparatus.

Step S800: releasing a carbon source gas G into the reaction chamber, and providing an alternative electric field to dissociate the carbon source gas G into a plasma carbon source C.

Step S1000: controlling the plasma carbon source C to be deposited on top surfaces of the plurality of bit line structures to form a carbon overcoat 7.

Step S1200: etching the sacrificial layer 5 and a part of the substrate to form a storage node contact hole.

Step S1400: removing the carbon overcoat 7.

In the method for fabricating a semiconductor device provided by the present disclosure, the plasma carbon source C is generated by dissociating the carbon source gas, and the plasma carbon source C is controlled to be deposited on the top of the bit line structure 4 to form a carbon overcoat 7. During etching, for the bit line structure 4, the carbon overcoat 7 may be etched instead of directly etching the top of the bit line structure 4. After the etching is completed, the bit line structure 4 is not damaged and its size is not deviated. In this way, dimensional accuracy of the semiconductor device is guaranteed, and yield of the semiconductor device is improved.

The method for fabricating a semiconductor device according to the embodiments of the present disclosure will be described in detail below.

Step S200: forming a plurality of bit line structures spaced on a substrate of the semiconductor device, the plurality of bit line structures extending along a first direction F1.

The semiconductor device may be a wafer, which is not limited here. As shown in FIG. 2 and FIG. 3, schematic structural diagrams of the semiconductor device are shown. The semiconductor device includes a semiconductor substrate 1 on which shallow trench isolations 2 are formed, and an active region is provided between the shallow trench isolations 2. The semiconductor substrate 1 is also provided with a word line structure (not shown in the figure) and a bit line structure 4. The word line structure and the bit line structure 4 are provided at different heights of the substrate 1, and the word line structure and the bit line structure 4 both are connected to the active region. The word line structure may include a high-k dielectric layer, a polysilicon layer, a work function layer, a word line metal layer, and the like.

In an embodiment, a material of the substrate 1 of the semiconductor device of the embodiments of the present disclosure may be silicon, silicon carbide, silicon nitride, silicon on insulator, stacked silicon on insulator, stacked silicon germanium on insulator, and silicon germanium on insulator or germanium on insulator, etc.

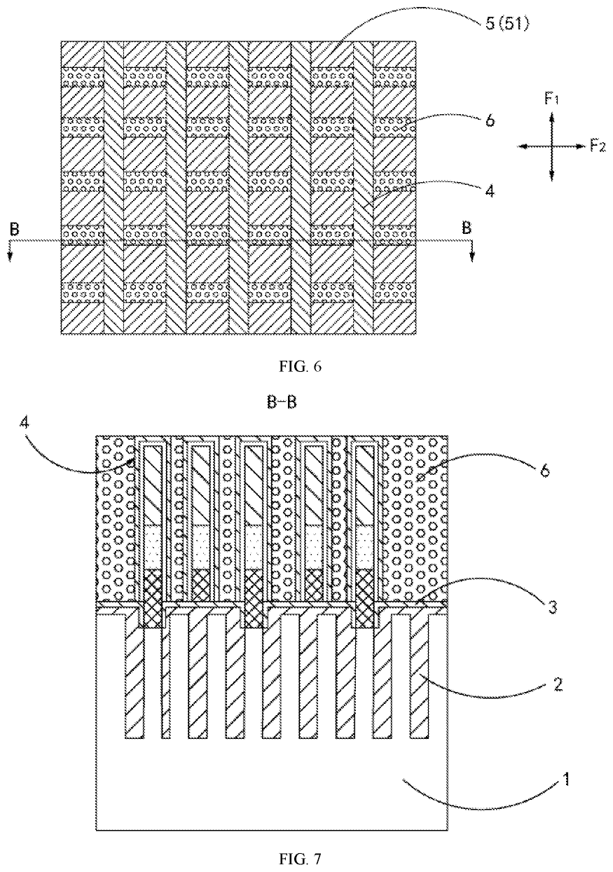

As shown in FIGS. 1 to 3, Step S200 of forming a plurality of bit line structures 4 spaced on a substrate 1 of the semiconductor device, as shown in FIG. 6, the plurality of bit line structures 4 extending along a first direction F1 may include:

Step S201: forming a plurality of bit line node plug holes H2 on the substrate 1.

In some embodiments, as shown in FIG. 2, an insulating layer 3 is first formed on the semiconductor substrate 1, and the insulating layer 3 is patterned by using a mask pattern as an etching mask to form a plurality of openings. Next, the substrate 1 within the plurality of openings is etched by means of an etching process to form a plurality of bit line node plug holes H2 at least partially positioned in the active region of the substrate 1. The plurality of bit line node plug holes H2 are configured to form a plurality of bit line contact plugs 411 and a plurality of bit line 412 connecting the active region.

Step S202: forming a bit line contact plug 411 in each of the plurality of bit line node plug holes H2.

In some embodiments, the bit line contact plug 411 may be formed in each of the plurality of bit line node plug holes H2 by means of a deposition method. In some embodiments, the bit line contact plug 411 may be formed by means of an atomic layer deposition process or a chemical vapor deposition process. The bit line contact plug 411 may be metal silicide, polysilicon, metal nitride, or metal, and is not limited thereto.

Step S203: forming a bit line 412 on a top of each of the plurality of bit line contact plugs 411.

In some embodiments, as shown in FIG. 2, the bit line 412 may be formed on each of the plurality of bit line contact plugs 411 by means of a deposition method. In some embodiments, the bit line 412 may be formed by means of an atomic layer deposition process or a chemical vapor deposition process. The bit line 412 may be metal. The bit line contact plug 411 and the bit line 412 may be made from the same material, and may be formed by the same deposition step, which is not limited here.

Step 5204: forming an insulating cover layer 413 on a top of each of the plurality of bit lines 412, such that the plurality of bit line contact plugs 411, the plurality of bit lines 412 and the plurality of insulating cover layers 413 form a bit line mandrel structure 41.

In some embodiments, the insulating cover layer 413 may be formed on each of the plurality of bit lines 412 by means of a deposition method. In some embodiments, the insulating cover layer 413 may be formed by means of an atomic layer deposition process or a chemical vapor deposition process. The insulating cover layer 413 may be silicon nitride or silicon oxynitride, and is not limited thereto. The insulating cover layer 413 insulates the top of the bit line 412 and plays a protective role.

Step 5205: forming a spacer layer 42 on a top and a sidewall of the bit line mandrel structure 41.

In some embodiments, as shown in FIG. 3, an insulating spacer layer 42 may be conformally formed on the top and the sidewall of the bit line mandrel structure 41 by means of a deposition method to form the bit line structure 4. In some embodiments, the spacer layer 42 may be formed by means of an atomic layer deposition process or a chemical vapor deposition process. Of course, in an actual operation process, the spacer layer 42 (not shown in the figure) may also be deposited on the substrate 1 between the bit line structures 4, and may be removed by means of an etching process. The spacer layer 42 may be silicon nitride, silicon oxide, or silicon oxynitride.

Further, referring to FIG. 3, the spacer layer 42 may have a first spacer layer 421 and a second spacer layer 422. The first spacer layer 421 is conformally deposited on the top and the sidewall of the bit line mandrel structure 41 by means of the above deposition process, and then the second spacer layer 422 is conformally formed on the first spacer layer 421. The first spacer layer 421 may be silicon dioxide (SiO₂), and the second spacer layer may be silicon nitride (Si₃N₄). Of course, the spacer layer 42 may also have three, four or more layers. By setting the spacer layer 42 into a plurality of layers, the spacer layer 42 formed during the deposition process is more uniform and has a more precise size. Furthermore, if one layer of the spacer layer 42 is provided, when the spacer layer 42 has a larger thickness is deposited unevenly, stress is easily generated inside the spacer layer 42, thereby having a negative effect on stability of performance of the semiconductor device. In contrast, arrangement of a plurality of layers of the spacer layers 42 can avoid stress, such that the stability of the semiconductor device is improved. Of course, if a thinner spacer layer 42 is formed, only one layer of spacer layer 42 may be provided. Number of layers of the spacer layer 42 may be set by those skilled in the art according to actual situations, and is not limited here.

By providing the insulating cover layer 413 and the spacer layer 42 on the top and the sidewall of the bit line 412, the bit line 412 is protected, such that a parasitic capacitance is reduced, and leakage current is prevented.

Step 5400 of forming a sacrificial layer 5 between the plurality of bit line structures includes following steps.

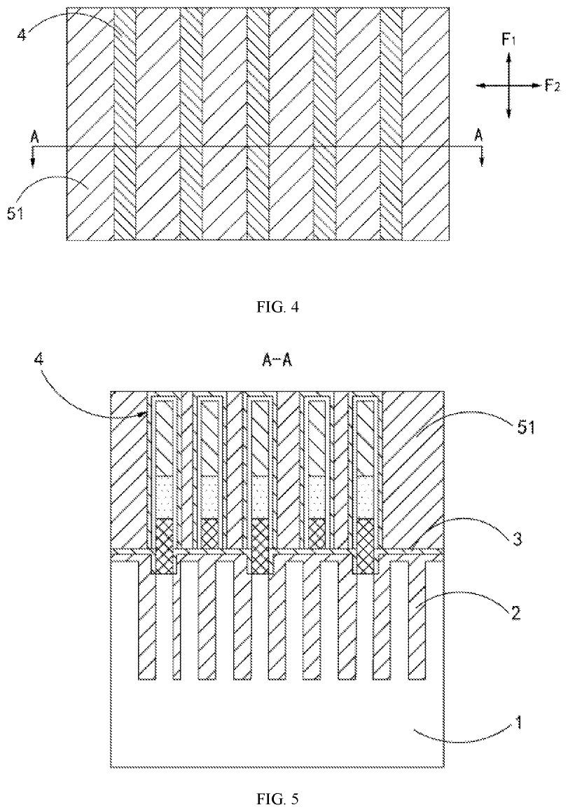

Step 5401: filling an initial sacrificial layer 51 between the plurality of bit line structures, as shown in FIG. 4 and FIG. 5.

Step 5402: forming a plurality of photoresist patterns (not shown in the figure) spaced on the initial sacrificial layer 51, each of the plurality of photoresist patterns extending in a second direction F2.

The second direction F2 intersects with the first direction F1. That is, an included angle may be provided between the second direction F2 and the first direction F1, wherein the included angle may be 90° or an acute angle, which is not limited here.

Step 5403: etching a part of the initial sacrificial layer 51 by using the plurality of photoresist patterns as a mask to form a blind hole, until a bottom of the blind hole exposes the substrate.

Step 5404: forming a spacer layer 6 to fill the blind hole, as shown in FIG. 6 and FIG. 7.

In some embodiments, the spacer layer 6 is filled in the blind hole by means of a deposition method. A material of the spacer layer 6 may be silicon nitride or silicon oxynitride. In an embodiment, the spacer layer 6 may be higher than the bit line structure. That is, the spacer layer 6 may be deposited on the top of the bit line structure in addition to being filled in the blind hole, to avoid causing damage to a top surface of the bit line structure in the subsequent process. The spacer layer 6 at the top may be removed together with the sacrificial layer 5.

Step S405: removing the plurality of photoresist patterns, the remaining initial sacrificial layer 51 being the sacrificial layer.

A material of the initial sacrificial layer 51 is the same as that of the sacrificial layer 5, which may be silicon nitride, silicon oxide or silicon oxynitride, and is not limited thereto.

Step S600: placing the semiconductor device in a reaction chamber of an etching apparatus.

In some embodiments, the above-mentioned semiconductor device on which the bit line structure 4 and the sacrificial layer 5 are formed is placed in the reaction chamber of the etching apparatus. The etching apparatus is internally provided with the reaction chamber, which may house the semiconductor device and process the semiconductor device. The etching apparatus is a dry etching apparatus. For example, the etching apparatus may be a plasma etching apparatus.

Step S800: releasing a carbon source gas G into the reaction chamber, and providing an alternative electric field to dissociate the carbon source gas G into a plasma carbon source C, as shown in FIG. 8.

The carbon source gas G may be at least one of CH₄, C₂H₆, and C₄H₈. As shown in FIG. 8, the carbon source gas G may be dissociated in the alternative electric field to generate a carbon-containing plasma. In one embodiment, the carbon source gas G is CH₄, and its chain reaction is as follows:

CH₄→CH₃⋅+H

CH₄→CH₂⋅+2H

CH₄→CH⋅+3H

CH₄→C⋅+4H

In a process of dissociation, a dissociation power of the controlled alternative electric field is 1,000 to 1,500 W. For example, the dissociation power may be 1,200 W, 1,300 W or 1,400 W. A dissociation frequency of the controlled alternative electric field is 10˜20 MHz. For example, the dissociation frequency may be 12 MHz, 15 MHz, or 18 MHz, and is not limited thereto. By controlling the above parameters of the alternative electric field, the carbon source gas G can be plasma-dissociated to form the plasma carbon source C.

Further, in the process of dissociation, a vacuum pressure in the reaction chamber may be controlled to be 20-40 mtorr, for example, 25 mtorr, 30 mtorr or 35 mtorr, and a temperature may be controlled to be 30° C. to 40° C., which is not limited here. Under the above conditions, CH₄ can be quickly dissociated into the plasma carbon source C.

Step S1000: controlling the plasma carbon source C to be deposited on top surfaces of the plurality of bit line structures 4 to form a carbon overcoat 7.

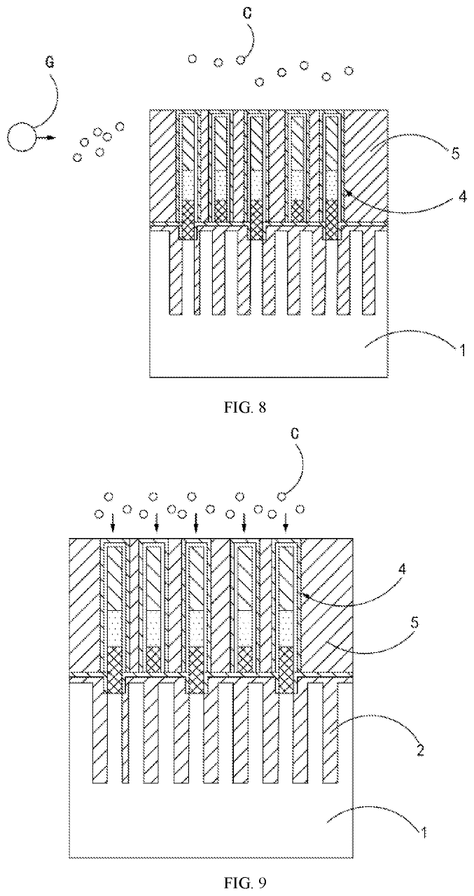

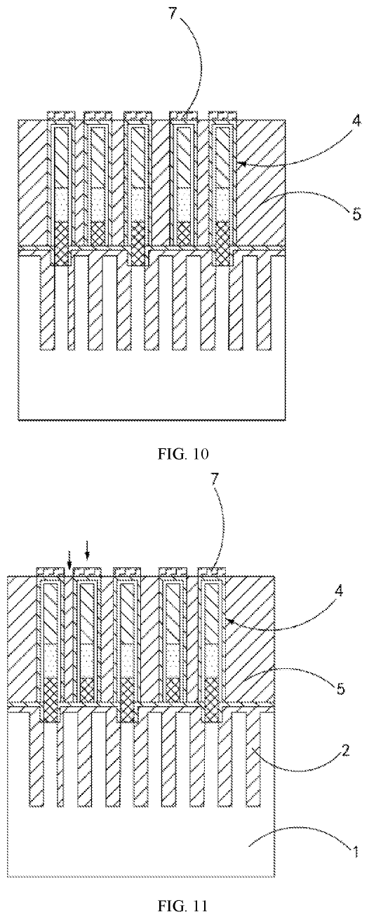

In some embodiments, as shown in FIG. 9 and FIG. 10, after the plasma carbon source C is generated, the plasma carbon source C floats in the reaction chamber. To control the plasma carbon source C to be deposited on the top surfaces of the plurality of bit line structures 4 in an orderly manner. A longitudinal bias power of the alternative electric field may be controlled to be 0˜10 W, for example, 2 W, 5 W, or 8 W. A longitudinal bias frequency of the alternative electric field may be controlled to be 500 KHz-5 MHz, for example, 800 KHz, 2 MHz or 4 MHz, and is not limited thereto.

Further, the vacuum pressure in the reaction chamber may be controlled to be 5-20 mtorr, for example, 8 mtorr, 10 mtorr, 15 mtorr or 18 mtorr, while the temperature is maintained at 30° C.-40° C. Based on the above adjustment, it is advantageous for the plasma carbon source C to be deposited on the top of the bit line structure 4.

Further, a thickness of the carbon overcoat 7 may be 2-40 nm, for example, 10 nm, 20 nm, or 30 nm. The thickness of the carbon overcoat 7 is controlled within this range, such that the carbon overcoat 7 can be removed to the greatest extent in the next etching step, without causing damage to the top of the bit line structure 4.

Step S1200: etching the sacrificial layer 5 and a part of the substrate to form a storage node contact hole.

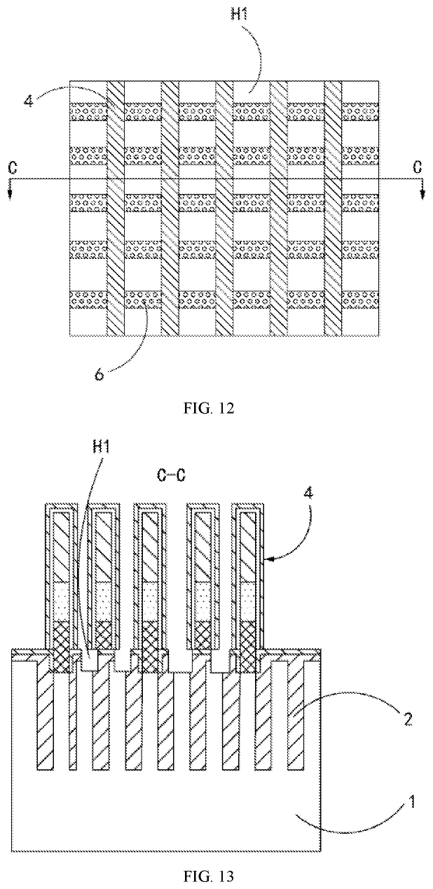

In some embodiments, as shown in FIGS. 11 to 13, the semiconductor device is etched by means of a dry etching process. The sacrificial layer 5 is etched first until the substrate is exposed, and then the substrate is further exposed to a certain depth to form the storage node contact hole. It is to be noted that FIG. 13 is a cross-sectional view of FIG. 12 along C-C. To clearly show that the sacrificial layer 5 is removed and the storage node contact hole H1 is formed, the spacer layer 6 is omitted in FIG. 13.

The dry etching may be plasma etching, and an etching gas used in the plasma etching process may be chlorine gas. By controlling dosage of the etching gas, an etching degree can be controlled. That is, the storage node contact hole H1 having a required depth can be formed.

In the above-mentioned etching process, by controlling etching conditions, the carbon overcoat 7 may also be etched to remove the carbon overcoat 7, without further etching the bit line structure 4, such that the size of the semiconductor device is more accurate, and the top of the bit line structure 4 is exposed. Of course, the etching conditions may also be controlled, such that in the process of etching to form the storage node contact holes, only a part of the carbon overcoat 7 is removed or the carbon overcoat 7 is not removed. After the etching is completed, the carbon overcoat 7 is removed by means of other processes.

Further, the carbon overcoat 7 may be removed by means of a plasma process, an ashing process, or a wet etching process.

In some embodiments, parameters in the plasma process, the ashing process, or the wet etching process may be controlled to increase a selection ratio of carbon, such that the carbon overcoat 7 can be removed separately without causing damage to other parts of the semiconductor device. In some embodiments, the plasma process may be performed by supplying at least one of H₂, N₂H₂, O₂ or CO at a plasma power of 300-800 W at a temperature of 200-400° C. and under a pressure of 3-8 Torr. In some embodiments, the ashing process may be performed by supplying a gas that generates hydrogen radicals or oxygen radicals at 200 to 400° C. The gas that can generate the hydrogen radicals or oxygen radicals may be NH₃, H₂, N₂O, O₂ or CO, and is not limited thereto. In some embodiments, in the wet etching process, the carbon overcoat 7 may be removed by means of concentrated sulfuric acid added with hydrogen peroxide.

By means of the above processes, the remaining carbon overcoat 7 can be completely removed, such that the top of the bit line structure 4 can be exposed. In this way, accuracy of the size of the semiconductor device is guaranteed, doping of impurities is avoided, and the stability of the performance of the semiconductor device is guaranteed.

Further, the method for fabricating a semiconductor device provided by the embodiments of the present disclosure also includes Step S1400: forming a storage node contact plug 8 in the storage node contact hole H1.

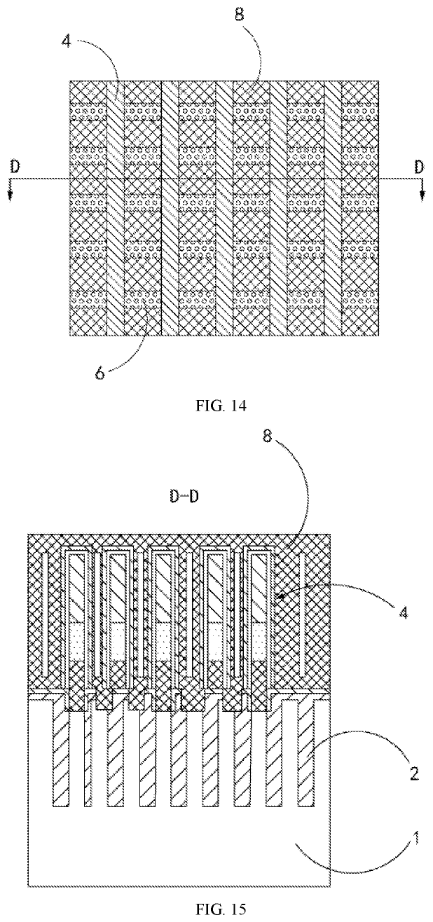

In some embodiments, as shown in FIG. 14 and FIG. 15, the storage node contact plug 8 may be formed in the storage node contact hole H1 by means of a deposition method. The storage node contact plug 8 may be metal silicide, polysilicon, metal nitride, or metal, and is not limited thereto. In addition, the bit line 412 is covered with a spacer, which can improve electrical insulation between the bit line 412 and the storage node contact plug 8, such that electrical interference or leakage current therebetween can be avoided.

Further, the method for fabricating a semiconductor device provided by the embodiments of the present disclosure also includes Step S1600: forming a data storage element on the storage node contact plug 8.

In some embodiments, the data storage element may include a capacitor of a bottom electrode, a capacitor of a dielectric, and a capacitor of a top electrode, such that the semiconductor device may be used as a dynamic random access memory (DRAM) device. In some embodiments, the data storage element forms a dielectric layer on a peripheral sidewall of the bottom electrode, and a top electrode layer is formed and covered on a dielectric layer. A high-K medium is selected as the dielectric layer to increase a capacitance value per unit area of the capacitor. A material of the dielectric layer may include at least one of ZrOₓ, HfOₓ, ZrTiOₓ, RuOₓ, SbOₓ, and AlOₓ, and the dielectric layer may also include a plurality of layers stacked by different materials. A material of the top electrode layer may be the same as that of a bottom electrode layer, which may include at least one of metal nitride and metal silicide species, such as titanium nitride, titanium silicide, nickel silicide, and the like. Both the above-mentioned dielectric layer and the top electrode layer may be formed by means of an atomic layer deposition process or a chemical vapor deposition process.

In conclusion, in the method for fabricating a semiconductor device provided by the present disclosure, the plasma carbon source C is generated by dissociating the carbon source gas G, and the plasma carbon source C is controlled to be deposited on the top of the bit line structure 4 to form the carbon overcoat 7. During etching, for the bit line structure 4, the carbon overcoat 7 may be etched instead of directly etching the top of the bit line structure 4. After the etching is completed, the bit line structure 4 is not damaged and its size is not deviated. In this way, dimensional accuracy of the semiconductor device is guaranteed, and yield of the semiconductor device is improved.

It is to be understood that the present disclosure does not limit its application to the detailed structure and arrangement of the components proposed in this specification. The present disclosure may have other embodiments and can be implemented and carried out in various ways. Variations and modifications of the foregoing are within the scope of the present disclosure. It is to be understood that the present disclosure disclosed and defined in this specification extends to all alternative combinations of two or more individual features that are mentioned or apparent from the text and/or drawings. All of these different combinations constitute various alternative aspects of the present disclosure. The embodiments described herein explain the best modes known for practicing the present disclosure and will enable those skilled in the art to utilize the present disclosure.

What is claimed is:

1. A method for fabricating a semiconductor device, comprising:
forming a plurality of bit line structures spaced on a substrate of the semiconductor device, the plurality of bit line structures extending along a first direction;
forming a sacrificial layer between the plurality of bit line structures;
placing the semiconductor device in a reaction chamber of an etching apparatus;
releasing a carbon source gas into the reaction chamber, and providing an alternative electric field to dissociate the carbon source gas into a plasma carbon source;
controlling the plasma carbon source to be deposited on top surfaces of the plurality of bit line structures to form a carbon overcoat;
etching the sacrificial layer and a part of the substrate to form a storage node contact hole; and
removing the carbon overcoat.

2. The method for fabricating a semiconductor device according to claim 1, wherein the releasing a carbon source gas into the reaction chamber, and providing an alternative electric field to dissociate the carbon source gas into a plasma carbon source comprise:
controlling a dissociation power of the alternative electric field to range from 1,000 W to 1,500 W, and a dissociation frequency thereof to range from 10 MHz to 20 MHz.

3. The method for fabricating a semiconductor device according to claim 2, wherein a vacuum pressure in the reaction chamber is controlled to range from 20 mtorr to 40 mtorr, a temperature in the reaction chamber being controlled to range from 30° C. to 40° C.

4. The method for fabricating a semiconductor device according to claim 1, wherein the controlling the plasma carbon source to be deposited on top surfaces of the plurality of bit line structures comprises:
controlling a longitudinal bias power of the alternative electric field to range from 0 to 10 W, and a longitudinal bias frequency thereof to range from 500 KHz to 5 MHz.

5. The method for fabricating a semiconductor device according to claim 4, wherein a vacuum pressure in the reaction chamber is controlled to range from 5 mtorr to 20 mtorr, a temperature in the reaction chamber being controlled to range from 30° C. to 40° C.

6. The method for fabricating a semiconductor device according to claim 1, wherein the carbon overcoat has a thickness of 2-40 nm.

7. The method for fabricating a semiconductor device according to claim 1, wherein the carbon source gas comprises at least one of CH₄, C₂H₆, and C₄H₈.

8. The method for fabricating a semiconductor device according to claim 1, wherein the sacrificial layer and the part of the substrate are etched by means of a dry etching process to form the storage node contact hole.

9. The method for fabricating a semiconductor device according to claim 1, wherein the carbon overcoat is removed by means of a plasma process, an ashing process, or a wet etching process.

10. The method for fabricating a semiconductor device according to claim 1, wherein the forming a sacrificial layer between the plurality of bit line structures comprises:
filling an initial sacrificial layer between the plurality of bit line structures;
forming a plurality of photoresist patterns spaced on the initial sacrificial layer, each of the plurality of photoresist patterns extending in a second direction, the second direction intersecting with the first direction;
etching a part of the initial sacrificial layer by using the plurality of photoresist patterns as a mask to form a blind hole, until a bottom of the blind hole exposes the substrate;
forming a spacer layer to fill the blind hole; and
removing the plurality of photoresist patterns, the remaining initial sacrificial layer being the sacrificial layer.

11. The method for fabricating a semiconductor device according to claim 10, wherein the sacrificial layer is silicon nitride, silicon oxide, or silicon oxynitride.

12. The method for fabricating a semiconductor device according to claim 10, wherein the spacer layer is silicon nitride or silicon oxynitride.

13. The method for fabricating a semiconductor device according to claim 1, further comprising:
forming a storage node contact plug in the storage node contact hole.

14. The method for fabricating a semiconductor device according to claim 13, wherein the storage node contact plug is metal silicide, polysilicon, metal oxynitride, or metal.

15. The method for fabricating a semiconductor device according to claim 13, wherein a data storage element is formed on the storage node contact plug.

16. The method for fabricating a semiconductor device according to claim 1, wherein the forming a plurality of bit line structures spaced on a substrate of the semiconductor device comprises:
forming a plurality of bit line node plug holes on the substrate;
forming a bit line contact plug in each of the plurality of bit line node plug holes;
forming a bit line on a top of each of a plurality of bit line contact plugs;
forming an insulating cover layer on a top of each of a plurality of bit lines, such that the plurality of bit line contact plugs, the plurality of bit lines and the plurality of insulating cover layers form a bit line mandrel structure; and
forming a spacer layer on a top and a sidewall of the bit line mandrel structure.

17. The method for fabricating a semiconductor device according to claim 16, wherein the spacer layer has a first spacer layer and a second spacer layer, the first spacer layer being formed on the top and the sidewall of the bit line mandrel structure, and then the second spacer layer being formed on the first spacer layer.

18. The method for fabricating a semiconductor device according to claim 17, wherein the first spacer layer is silicon dioxide, the second spacer layer being silicon nitride.
